(19) United States
(12) Patent Application Publication
(10) Pub. No.: US 2022/0146216 A1
(43) Pub. Date: May 12, 2022

(54) COPPER-ALLOY HEAT-DISSIPATION STRUCTURE WITH MILLED SURFACE

(71) Applicant: AMULAIRE THERMAL TECHNOLOGY, INC., New Taipei City (TW)

(72) Inventors: MIN-HORNG LIU, NEW TAIPEI CITY (TW); TZE-YANG YEH, New Taipei City (TW)

(21) Appl. No.: 17/583,374

(22) Filed: Jan. 25, 2022

Related U.S. Application Data
(63) Continuation-in-part of application No. 16/711,726, filed on Dec. 12, 2019.

(51) Int. Cl. F28F 21/08; F28F 3/02; B23P 15/26

(52) U.S. Cl. CPC F28F 21/085; B23P 15/26; F28F 3/02; F28F 21/089

(57) ABSTRACT

A copper-alloy heat-dissipation structure with a milled surface includes a heat-dissipation main body. The heat-dissipation main body has a first milled surface and a second milled surface that are opposite to each other, where heat-dissipation fins are formed on the first milled surface, and the maximum height roughness Rz of the second milled surface ranges from 2.5 μm to 5.4 μm.

### CROSS-REFERENCE TO RELATED PATENT APPLICATION

This Application is a Continuation-in-Part of application Ser. No. 16/711,726 filed Dec. 12, 2019, now pending, and entitled copper-alloy heat-dissipation structure with milled surface.

### FIELD OF THE DISCLOSURE

The present disclosure relates to a heat dissipation structure, and more particularly, to a copper-alloy heat-dissipation structure with a milled surface.

### BACKGROUND OF THE DISCLOSURE

In order to make heat dissipation more efficient, some heat sinks are made from a copper alloy. However, the copper alloy fabricated by means of powder metallurgy is generally porous. During fabrication, the final diameters of pores in a metal porous material are affected by various factors, such as fineness, distribution, shapes, and sintering temperature of selected powders. FIG. 1 schematically shows a heat sink 1A made from a copper alloy, which has surface pores 11A. Consequently, a void 13A is easily formed in tin solder 12A after soldering (as shown in FIG. 2), greatly reducing the quality of solder bonding.

In view of this, the inventor of the present disclosure has conceived of improvements to the related art after years of experience in development and design of related products, and based on deep study and application of relevant theory, finally proposed the heat-dissipation structure of the present disclosure that is sensibly designed and that can effectively alleviate the foregoing issue.

### SUMMARY OF THE DISCLOSURE

The main objective of the present disclosure is to provide a copper-alloy heat-dissipation structure with a milled surface, so as to solve the foregoing issue.

To solve the foregoing technical issue, a technical solution adopted by the present disclosure is to provide a copper-alloy heat-dissipation structure with a milled surface, which includes a heat-dissipation main body. The heat-dissipation main body has a first milled surface and a second milled surface that are opposite each other. A first nickel plating layer is formed on the first milled surface and the heat-dissipation fins. A second nickel plating layer is formed on the second milled surface. A tin solder is formed on the second nickel plating layer. The second milled surface has a maximum height roughness RZ greater than 2.5 μm and an average length Rsm less than 0.50 mm.

In an exemplary embodiment, the first nickel plating layer and the second nickel plating layer are each an electro-plated nickel layer, and thickness of each of the first nickel plating layer and the second nickel plating layer ranges from 2 μm to 6 μm.

In an exemplary embodiment, the first nickel plating layer and the second nickel plating layer are each an electroless nickel plating layer containing 2% to 4% by weight of phosphorus, and thickness of each of the first nickel plating layer and the second nickel plating layer ranges from 4 μm to 6 μm.

In an exemplary embodiment, the heat-dissipation main body is made from a porous copper alloy.

In an exemplary embodiment, the heat-dissipation main body contains nickel, chrome, cobalt, and copper.

In an exemplary embodiment, the first milled surface and the second milled surface are formed by milling.

Therefore, in the copper-alloy heat-dissipation structure with a milled surface provided by the present disclosure, a heat-dissipation main body has a first milled surface and a second milled surface which are opposite to each other, and the maximum height roughness Rz of the second milled surface ranges from 2.5 μm to 5.4 μm. In this way, surface pores are avoided in the heat-dissipation main body, and thus voids are further avoided in tin solder after soldering, thereby improving the quality of solder bonding. Moreover, an average length Rsm of roughness curves of the second milled surface ranges from 0.05 mm to 0.50 mm. Thus, the surface can be highly refined, and further, a stable and regular surface condition can stabilize the quality of solder bonding.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 schematically shows a heat sink in the related art;

FIG. 2 schematically shows a heat sink and tin solder thereon in the related art;

FIG. 3 schematically shows a copper-alloy heat-dissipation structure with a milled surface in the present disclosure;

FIG. 4 schematically shows the maximum height roughness and an average length of roughness curves of a second milled surface in the present disclosure;

FIG. 5 schematically shows a copper-alloy heat-dissipation structure with a milled surface and tin solder thereon in the present disclosure;

FIG. 6 schematically shows another copper-alloy heat-dissipation structure with a milled surface and tin solder thereon in the present disclosure; and

FIG. 7 schematically shows still another copper-alloy heat-dissipation structure with a milled surface and tin solder thereon in the present disclosure.

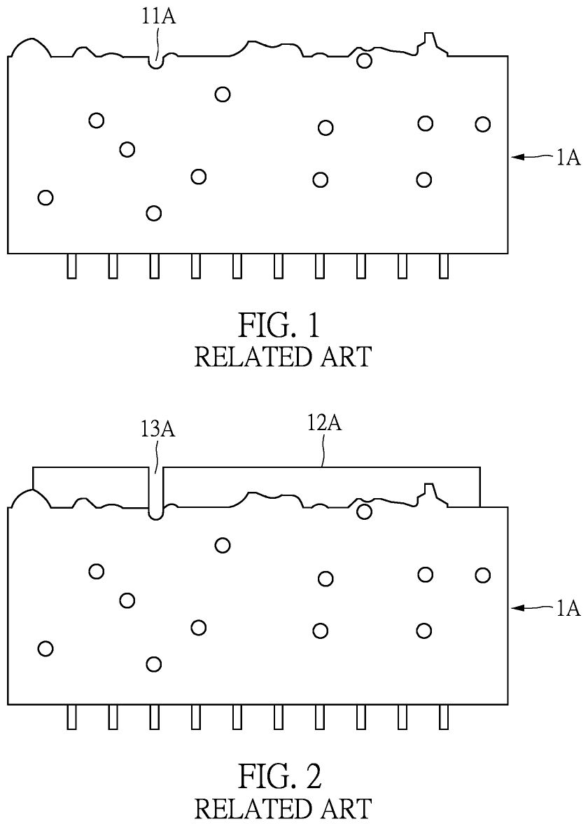

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

The following describes an implementation disclosed by the present disclosure by using a specific embodiment. Persons skilled in the art can understand the advantages and effects of the present disclosure from the content disclosed in the specification. The present disclosure can be embodied or applied through other different embodiments. Based on different opinions and applications, details of the present specification can also be modified and changed without departing from the concepts of the present disclosure. In addition, it should be stated beforehand that, the accompanying drawings of the present disclosure are merely for brief illustration and not drawn according to actual dimensions. The following implementation will further explain related technical content of the present disclosure, but the disclosed content is not intended to limit the scope of the present disclosure.

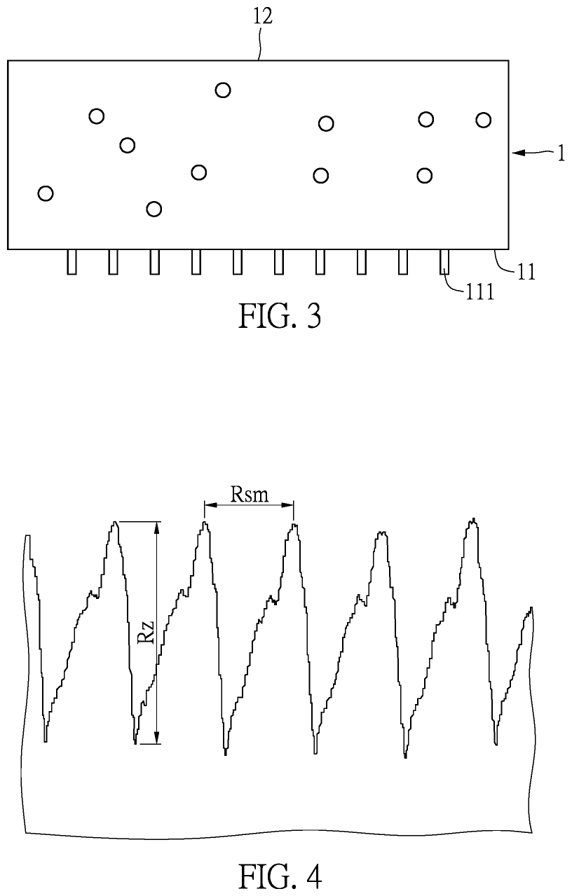

Refer to FIG. 3, which schematically shows a copper-alloy heat-dissipation structure with a milled surface in the present disclosure. As shown in FIG. 3, the copper-alloy heat-dissipation structure with a milled surface in the present disclosure has a heat-dissipation main body 1.

The heat-dissipation main body 1 is exemplarily made from a copper alloy, but can also be made from an aluminum alloy, a magnesium alloy, or a titanium alloy.

In this embodiment, the heat-dissipation main body 1 is made from a copper alloy, thus achieving optimal heat conduction. In further detail, the copper alloy used for fabricating the heat-dissipation main body 1 contains nickel (Ni), chrome (Cr), cobalt (Co), copper (Cu), and inevitable impurities. The inevitable impurities are substances that exist in the raw materials or inevitably pass into the alloy during fabrication but do not affect the properties of the copper alloy, and therefore are considered acceptable impurities.

Specifically, the copper alloy, for example, can contain 1.5 to 3.6 weight percent nickel, 0.20 to 0.40 weight percent chrome, and 0.01 to 0.15 weight percent cobalt, thus ensuring the strength of the copper alloy. In addition, the copper alloy can also contain 0.05 to 3.0 weight percent zinc (Zn), which can improve the quality of solder bonding.

Moreover, the shape and the thickness of the heat-dissipation main body 1 are not specifically limited, and can be appropriately adjusted as required. In this embodiment, the heat-dissipation main body 1 has a first milled surface 11 and a second milled surface 12 that are opposite each other.

Heat-dissipation fins 111 are formed on the first milled surface 11, and the shapes of the heat-dissipation fins 111 are not limited. The heat-dissipation main body 1 and the heat-dissipation fins 111 may be integrally formed, or they may be separately formed and then joined by welding or stamping. In this embodiment, the heat-dissipation main body 1 and the heat-dissipation fins 111 on its first milled surface 11 are integrally formed. In further detail, the heat-dissipation fins 111 may be formed by means of mechanical processing (cutting or grinding).

The second milled surface 12 is formed on one side of the heat-dissipation main body 1 by a milling process. Therefore, plastic deformation may be implemented within a certain range by a specific milling process, to eliminate surface pores from one side of the heat-dissipation main body 1 and achieve low surface roughness, thus improving the quality of solder bonding.

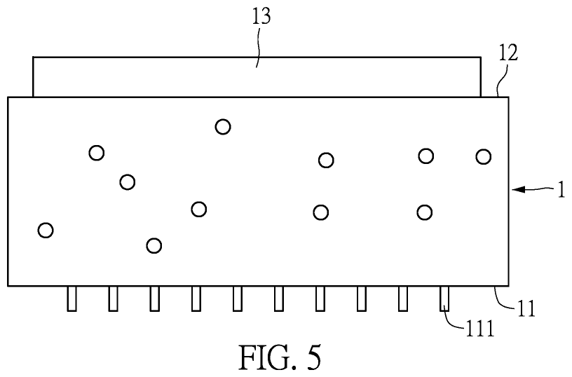

Referring to FIG. 4 and FIG. 5, FIG. 4 schematically shows the maximum height roughness Rz and an average length Rsm of roughness curves of the second milled surface 12 in this embodiment.

Specifically, the maximum height roughness Rz of the second milled surface 12 in this embodiment ranges from 2.5 μm to 5.4 μm. Within this range, the surface pores can be avoided, and voids can be further avoided in tin solder 13 after soldering, thereby improving the quality of solder bonding (as shown in FIG. 5). If the maximum height roughness Rz exceeds 5.4 μm, it would be difficult to meet a range of the average length Rsm of roughness curves described below.

More specifically, the average length Rsm of roughness curves of the second milled surface 12 in this embodiment ranges from 0.05 mm to 0.50 mm. Within this range, the second milled surface 12 can be highly refined. If the average length Rsm of the roughness curves exceeds 0.50 mm, intervals between tips of surface protrusions are increased, thus making it difficult to meet the range of the maximum height roughness Rz described above.

In addition, various milling processes can all be taken into consideration to achieve the maximum height roughness Rz and the average length Rsm of the roughness curves of the second milled surface 12.

Moreover, various milling tools, such as a face mill made from tungsten carbide steel and a bull end mill made from tungsten steel, can all be taken into consideration for use. However, the milling tools and their materials are not limited to the above description.

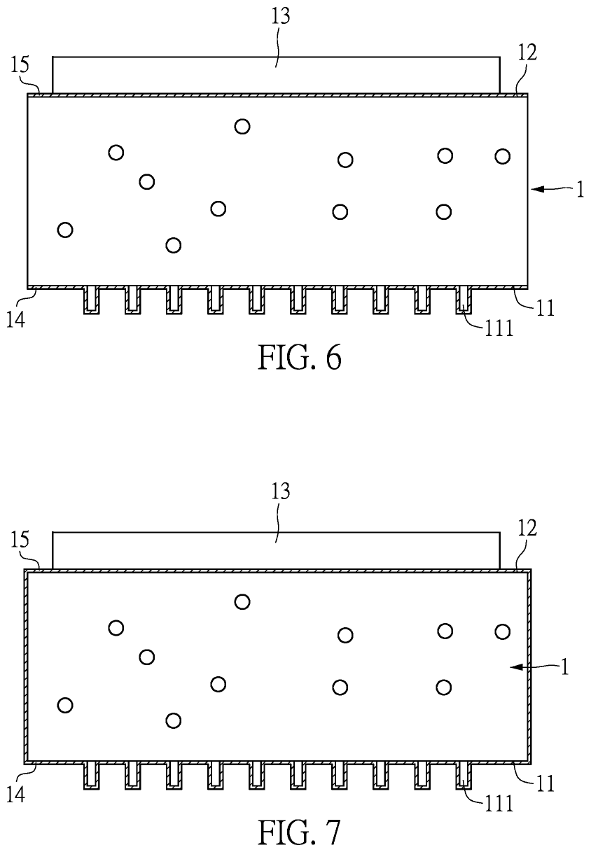

Refer to FIG. 6, which schematically shows another copper-alloy heat-dissipation structure with a milled surface in the present disclosure. As shown in FIG. 6, a first nickel plating layer 14 is formed on the first milled surface 11 and the heat-dissipation fins 111, a second nickel plating layer 15 is formed on the second milled surface 12, and a tin solder 13 is formed on the second nickel plating layer 15.

The first nickel plating layer 14 and the second nickel plating layer 15 having corrosion resistance properties can be used to protect the first milled surface 11 and the second milled surface 12 from corrosion. Further, the second nickel plating layer 15 can be used for improving the solderability of the second milled surface 12.

In one embodiment, the first nickel plating layer 14 and the second nickel plating layer 15 can each be an electro-plated nickel layer, and the thickness of each of the first nickel plating layer 14 and the second nickel plating layer 15 ranges from 2 μm to 6 μm, so as to effectively improve the corrosion resistance property and solderability of the copper-alloy heat-dissipation structure.

In one embodiment, the first nickel plating layer 14 and the second nickel plating layer 15 can each be an electroless nickel plating layer containing 2% to 4% by weight of phosphorus, and the thickness of each of the first nickel plating layer 14 and the second nickel plating layer 15 ranges from 4 μm to 6 μm, so as to more effectively improve the corrosion resistance property and solderability of the copper-alloy heat-dissipation structure.

In addition, the tin solder 13 formed on the second milled surface 12 can be melted in a subsequent process. Furthermore, a melting point of the tin solder 20 in this embodiment is defined to be between 220° C. and 240° C. The melting point is relatively low and a melting range is relatively narrow, so as to improve the bonding strength and quality.

In certain embodiments, the second nickel plating layer 15 may be formed by the electroless nickel plating layer and the electro-plated nickel layer thereon.

Refer to FIG. 7, which schematically shows still another copper-alloy heat-dissipation structure with a milled surface in the present disclosure. As shown in FIG. 7, the first nickel plating layer 14 and the second nickel plating layer 15 may be connected to form a layer that completely covers the heat-dissipation main body 1.

In conclusion, in the copper-alloy heat-dissipation structure with a milled surface provided by the present disclosure, a heat-dissipation main body 1 has a first milled surface 11 and a second milled surface 12 that are opposite to each other, and the maximum height roughness Rz of the second milled surface 12 ranges from 2.5 μm to 5.4 μm. In this way, surface pores are avoided in the heat-dissipation main body 1, and thus voids are further avoided in tin solder 13 after soldering, thereby improving the quality of solder bonding. Moreover, an average length Rsm of roughness curves of the second milled surface 12 ranges from 0.05 mm to 0.50 mm, such that the surface can be highly refined.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A copper-alloy heat-dissipation structure with a milled surface, comprising a heat-dissipation main body, wherein the heat-dissipation main body has a first milled surface and a second milled surface that are opposite to each other, heat-dissipation fins are formed on the first milled surface, a first nickel plating layer is formed on the first milled surface and the heat-dissipation fins, a second nickel plating layer is formed on the second milled surface, a tin solder is formed on the second nickel plating layer, and the second milled surface has a maximum height roughness RZ greater than 2.5 μm and an average length Rsm less than 0.50 mm.

2. The copper-alloy heat-dissipation structure with the milled surface of claim 1, wherein the first nickel plating layer and the second nickel plating layer are each an electro-plated nickel layer, and thickness of each of the first nickel plating layer and the second nickel plating layer ranges from 2 μm to 6 μm.

3. The copper-alloy heat-dissipation structure with the milled surface of claim 1, wherein the first nickel plating layer and the second nickel plating layer are each an electroless nickel plating layer containing 2% to 4% by weight of phosphorus, and thickness of each of the first nickel plating layer and the second nickel plating layer ranges from 4 μm to 6 μm.

4. The copper-alloy heat-dissipation structure with the milled surface of claim 1, wherein the heat-dissipation main body is made from a porous copper alloy.

5. The copper-alloy heat-dissipation structure with the milled surface of claim 1, wherein the heat-dissipation main body contains nickel, chrome, cobalt, and copper.
